(19) United States
(12) Patent Application Publication
(10) Pub. No.: US 2026/0123522 A1
(43) Pub. Date: Apr. 30, 2026

(54) ELECTRONIC DEVICE INCLUDING AN OUTERMOST LAYER HAVING OXIDE MATERIAL, ASSEMBLY STRUCTURE AND METHOD OF MANUFACTURING THE SAME

(71) Applicant: NANYA TECHNOLOGY CORPORATION, NEW TAIPEI CITY (TW)

(72) Inventor: WEI-CHUAN FANG, NEW TAIPEI CITY (TW)

(21) Appl. No.: 18/951,892

(22) Filed: Nov. 19, 2024

Related U.S. Application Data
(62) Division of application No. 18/929,989, filed on Oct. 29, 2024.

(51) Int. Cl. H01L 23/29; H01L 23/00; H01L 23/31; H01L 23/498; H05K 1/11

(52) U.S. Cl. CPC H10W 74/43; H05K 1/113; H10W 70/635; H10W 70/65; H10W 74/134; H05K 2201/09481; H10W 90/724

(57) ABSTRACT

An electronic device, an assembly structure and a manufacturing method are provided. The electronic device includes a base portion, a circuit structure, an insulation structure, a first conductive layer, a via structure, a first outer layer and a second outer layer. The circuit structure is disposed on a first surface of the base portion. The insulation structure is disposed on the circuit structure. The first conductive layer is disposed on the insulation structure. The via structure extends through the insulation structure, and electrically connects the first conductive layer and the circuit structure. The first outer layer is disposed on the first conductive layer. The second outer layer is disposed on the first outer layer. The second outer layer includes an oxide material so as to improve a coplanarity of an outermost surface of the second outer layer.

### CROSS-REFERENCE TO RELATED APPLICATION

This application is a divisional application of U.S. Non-Provisional Application No. Ser. No. 18/929,989 filed Oct. 29, 2024, which is incorporated herein by reference in its entirety.

### TECHNICAL FIELD

The present disclosure relates to an electronic device, an assembly structure and a method of manufacturing the same, and more particularly, to an electronic device including an outermost layer having oxide material, an assembly structure including the electronic device, and a method of manufacturing the same.

### DISCUSSION OF THE BACKGROUND

Semiconductor structures are used in a variety of electronic applications, and the dimensions of semiconductor structures are continuously being scaled down to meet the current application requirements. However, a variety of issues arise during the scaling-down process and impact the final electrical characteristics, quality, cost and yield. Typical semiconductor structure has a plurality of bumps disposed on its outer surface. If the outer surface is a wavy surface, the bumps will tilt or will have different elevations. Thus, a poor joint will be formed between the semiconductor structure and another electronic device, and the yield rate of the assembly structure will be lowered. Therefore, the coplanarity and flatness of the outer surface of the semiconductor structure is a critical issue.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides an electronic device. The electronic device includes a base portion, a circuit structure, an insulation structure, a first conductive layer, a via structure, a first outer layer and a second outer layer. The base portion has a first surface. The circuit structure is disposed on the first surface of the base portion. The insulation structure is disposed on the circuit structure. The first conductive layer is disposed on the insulation structure. The via structure extends through the insulation structure, and electrically connects the first conductive layer and the circuit structure. The first outer layer is disposed on the first conductive layer. The second outer layer is disposed on the first outer layer. The second outer layer includes an oxide material so as to improve a coplanarity of an outermost surface of the second outer layer.

Another aspect of the present disclosure provides an assembly structure. The assembly structure includes a first electronic device, a second electronic device and a substrate. The first electronic device includes a base portion, an outermost layer and a bump. The base portion has a first surface. The outermost layer is disposed adjacent to the first surface of the base portion. The outermost layer includes an oxide material so as to improve a coplanarity of an outermost surface of the outermost layer. The bump extends through the outermost layer and extends beyond the outermost surface of the outermost layer. The second electronic device includes a base portion, a through via, a pad and a connecting element. The base portion has a first surface and a second surface opposite to the first surface. The through via extends through the base portion. The pad is disposed adjacent to the second surface of the base portion of the second electronic device, and electrically connects the through via and the bump of the first electronic device. The connecting element is disposed adjacent to the first surface of the base portion of the second electronic device, and is electrically connected to the pad through the through via. The substrate is electrically connected to the connecting element.

Another aspect of the present disclosure provides a method of manufacturing an electronic device. The method includes: providing a main body including a base portion having a first surface, a circuit structure disposed on the first surface of the base portion, and an insulation structure disposed on the circuit structure; forming a through hole extending through the insulation structure; forming a first conductive layer on the insulation structure and forming an interconnection layer on a sidewall of the through hole, wherein the first conductive layer connects the interconnection layer, wherein the first conductive layer is electrically connected to the circuit structure through the interconnection layer; forming a first outer layer on the first conductive layer; and forming a second outer layer on the first outer layer, wherein the second outer layer includes an oxide material.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 illustrates, in a flowchart diagram form, a method of manufacturing an electronic device in accordance with one embodiment of the present disclosure.

FIGS. 2 to 15 illustrate stages of a method of manufacturing an assembly structure in accordance with one embodiment of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

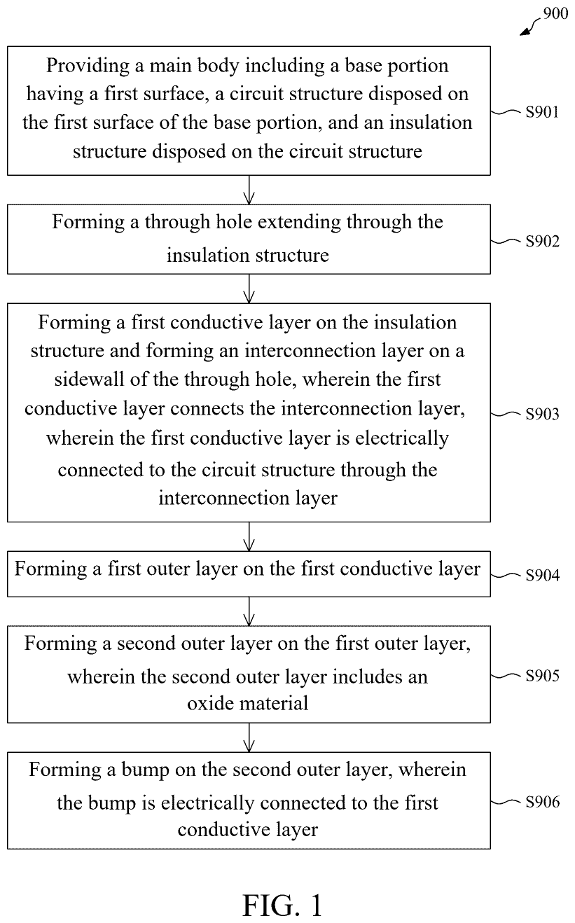

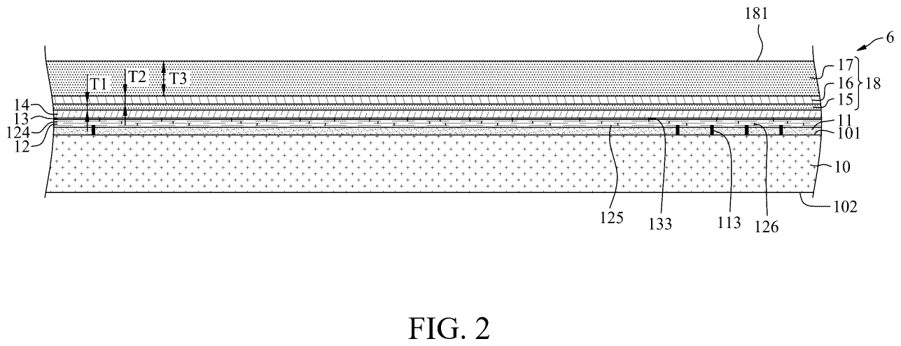

FIG. 1 illustrates, in a flowchart diagram form, a method 900 for manufacturing an electronic device 1 in accordance with one embodiment of the present disclosure. FIGS. 2 to 15 illustrate stages of a method for manufacturing an assembly structure 5 in accordance with one embodiment of the present disclosure. In some embodiments, FIGS. 2 to 10 illustrate stages of a method for manufacturing the electronic device 1 in accordance with one embodiment of the present disclosure. At least some of these figures have been simplified for a better understanding of the aspects of the present disclosure.

With reference to FIG. 2, at step S901, a main body 6 may be provided. The main body 6 may include a base portion 10, a first intermediate layer 11, a plurality of first interconnection vias 113, a circuit structure 12, a second intermediate layer 13, a plurality of second interconnection vias 133, a second conductive layer 14 and an insulation structure 18. The base portion 10 may have a first surface 101 and a second surface 102 opposite to the first surface 101. The first surface 101 may be an active surface. The second surface 102 may be a back side surface.

In some embodiments, the base portion 10 may be a substrate, and may include a dielectric material, such as an oxide material or a nitride material. Alternatively, the base portion 10 may be a substrate, and may include, for example, silicon (Si), germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

In some embodiments, the base portion 10 may be a semiconductor device that includes a circuit, such as a memory cell. In some embodiments, the memory cell may include a dynamic random access memory cell (DRAM cell).

In addition, the base portion 10 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof.

The first intermediate layer 11 may be disposed between the first surface 101 of the base portion 10 and the circuit structure 12. The first intermediate layer 11 may be also referred to as “a lower intermediate layer” or “an upper intermediate layer”. The first intermediate layer 11 may be configured to electrically insulate the circuit structure 12 form the first surface 101 of the base portion 10. Thus, the circuit structure 12 is electrically insulated form the first surface 101 of the base portion 10 through the first intermediate layer 11. In some embodiments, the first intermediate layer 11 may include a dielectric material or an electrical insulation material, such as an oxide material or a nitride material.

The first interconnection vias 113 may be disposed in the first intermediate layer 11. The first interconnection vias 113 may extend through the first intermediate layer 11, and may be configured to electrically connect the circuit structure 12 and the first surface 101 of the base portion 10. Thus, the circuit structure 12 is electrically connected to the first surface 101 of the base portion 10 through the first interconnection vias 113. In some embodiments, the first interconnection vias 113 may include an electrically conductive material, such as a metal material. For example, the first interconnection vias 113 may include copper (Cu).

The circuit structure 12 may be disposed on or disposed over the first intermediate layer 11 and the first surface 101 of the base portion 10. In some embodiments, the first intermediate layer 11 may be disposed on and may contact the first surface 101 of the base portion 10. The circuit structure 12 may be disposed on and may contact the first intermediate layer 11. Alternatively, there may be at least one layer (e.g., insulation layer or conductive layer) between the circuit structure 12 and the first surface 101 of the base portion 10.

The circuit structure 12 may be a redistribution layer (RDL) structure, and may include a plurality of dielectric layers 124, a plurality of redistribution layers (RDLs) 125 and a plurality of inner vias 126. The dielectric layers 124 may be interlayer dielectric (ILD) layers, and may include SiO₂, SiN, and/or SiCN. The redistribution layers (RDLs) 125 and the inner vias 126 are embedded in the dielectric layers 124. The redistribution layers (RDLs) 125 may include a plurality of traces and a plurality of pads. The redistribution layers (RDLs) 125 are electrically connected to one another through the inner vias 126. The circuit structure 12 may be also referred to as “a conductive structure”. In some embodiments, the redistribution layers (RDLs) 125 may be electrically connected to the first interconnection vias 113.

The second intermediate layer 13 may be disposed between the second conductive layer 14 and the circuit structure 12. The second intermediate layer 13 may be also referred to as “a lower intermediate layer” or “an upper intermediate layer”. The second intermediate layer 13 may be configured to electrically insulate the circuit structure 12 form the second conductive layer 14. Thus, the circuit structure 12 is electrically insulated form the second conductive layer 14 through the second intermediate layer 13. In some embodiments, the second intermediate layer 13 may include a dielectric material or an electrical insulation material, such as an oxide material or a nitride material.

The second interconnection vias 133 may be disposed in the second intermediate layer 13. The second interconnection vias 133 may extend through the second intermediate layer 13, and may be configured to electrically connect the circuit structure 12 and the second conductive layer 14. Thus, the circuit structure 12 is electrically connected to the second conductive layer 14 through the second interconnection vias 133. In some embodiments, the second interconnection vias 133 may include an electrically conductive material, such as a metal material. For example, the second interconnection vias 133 may include copper (Cu).

The second conductive layer 14 may be disposed between the circuit structure 12 and the insulation structure 18. In some embodiments, the second intermediate layer 13 may cover and contact the circuit structure 12. The second conductive layer 14 may be interposed between the second intermediate layer 13 and the insulation structure 18. In some embodiments, the second conductive layer 14 may include a metal layer such as an aluminum (Al) layer or a copper (Cu) layer, and may cover and contact the second intermediate layer 13. The second conductive layer 14 may be electrically connected to the circuit structure 12 through the second interconnection vias 133.

The insulation structure 18 may be disposed on or disposed over the circuit structure 12. In some embodiments, the insulation structure 18 may cover and contact the second conductive layer 14. The insulation structure 18 may include a first insulation layer 15, a second insulation layer 16 and a third insulation layer 17. Thus, the first insulation layer 15, the second insulation layer 16 and the third insulation layer 17 may collectively define the insulation structure 18. The insulation structure 18 may have a first surface 181 (e.g., a top surface) facing away from the circuit structure 12 and the base portion 10.

The first insulation layer 15 may be disposed on or disposed over the circuit structure 12. The first insulation layer 15 may cover and contact the second conductive layer 14. The first insulation layer 15 may be a passivation layer or an electrical insulation layer, and may include an oxide material or a nitride material, such as SiO₂, SiN, Si₃N₄ and/or SiCN. The first insulation layer 15 may be a buffer layer. The first insulation layer 15 may have a first thickness T1.

The second insulation layer 16 may be disposed on or disposed over the first insulation layer 15. The second insulation layer 16 may be interposed between the first insulation layer 15 and the third insulation layer 17. The second insulation layer 16 may cover and contact the first insulation layer 15. The second insulation layer 16 may be a passivation layer or an electrical insulation layer, and may include an oxide material or a nitride material, such as SiO₂, SiN, Si₃N₄ and/or SiCN. The second insulation layer 16 may be a protection layer and may prevent the external moisture from entering the circuit structure 12 and the first surface 101 of the base portion 10. A material of the second insulation layer 16 may be different from a material of the first insulation layer 15. The second insulation layer 16 may have a second thickness T2.

The third insulation layer 17 may be disposed on or disposed over the second insulation layer 16. The third insulation layer 17 may cover and contact the second insulation layer 16. A first surface (e.g., a top surface) of the third insulation layer 17 may be the first surface 181 (e.g., the top surface) of the insulation structure 18. The third insulation layer 17 may be a passivation layer or an electrical insulation layer, and may include an oxide material or a nitride material, such as SiO₂, SiN, Si₃N₄ and/or SiCN. The third insulation layer 17 may have a third thickness T3. A material of the third insulation layer 17 may be the same as the material of the first insulation layer 15. The material of the third insulation layer 17 may be different from the material of the second insulation layer 16. For example, the third insulation layer 17 may include oxide material, the first insulation layer 15 may include oxide material, and the second insulation layer 16 may include nitride material.

The third thickness T3 of the third insulation layer 17 may be greater than the second thickness T2 of the second insulation layer 16 and the first thickness T1 of the first insulation layer 15. The second thickness T2 of the second insulation layer 16 may be greater than the first thickness T1 of the first insulation layer 15. In some embodiments, the first thickness T1 of the first insulation layer 15 may be 0.6 μm to 1.0 μm. For example, the first thickness T1 of the first insulation layer 15 may be about 0.8 μm. In some embodiments, the second thickness T2 of the second insulation layer 16 may be 0.8 μm to 1.2 μm. For example, the second thickness T2 of the second insulation layer 16 may be about 0.8 μm. In some embodiments, the third thickness T3 of the third insulation layer 17 may be 4.0 μm to 5.0 μm. For example, the third thickness T3 of the third insulation layer 17 may be about 4.5 μm.

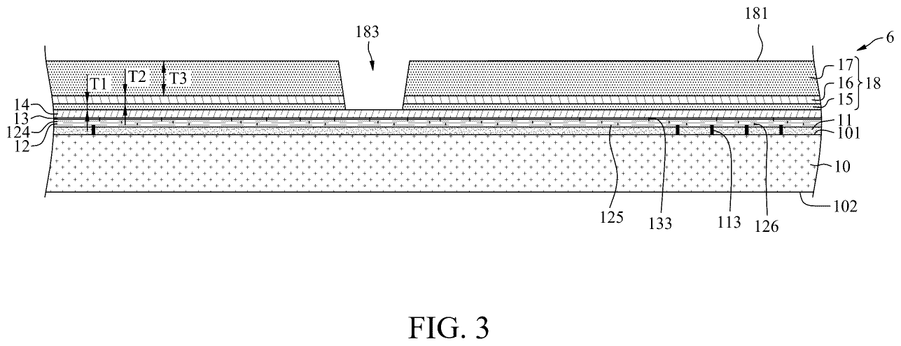

With reference to FIG. 3, at step S902, a through hole 183 may be formed to extend through the insulation structure 18. The through hole 183 may be recessed from the first surface 181 (e.g., the top surface) of the insulation structure 18. The through hole 183 may extend through the first insulation layer 15, the second insulation layer 16 and the third insulation layer 17 to expose a portion of the second conductive layer 14. Thus, the insulation structure 18 may define the through hole 183 extending through the insulation structure 18.

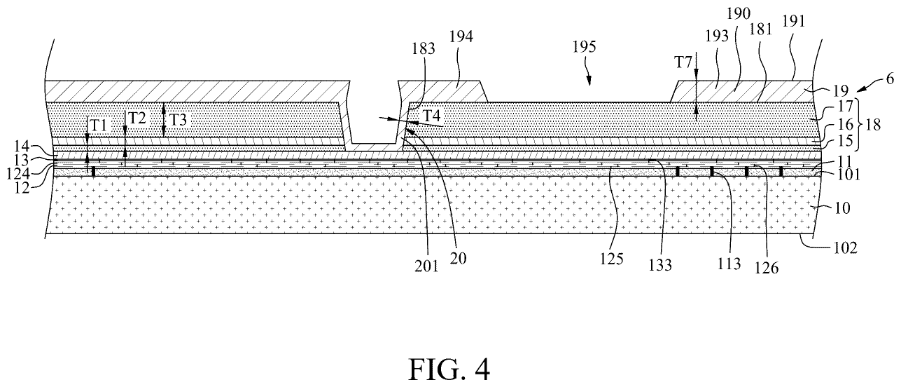

With reference to FIG. 4, at step S903, a first conductive layer 19 may be formed or disposed on the first surface 181 (e.g., the top surface) of the insulation structure 18. The first conductive layer 19 may have a first surface 191 (e.g., a top surface) facing away from the first surface 181 (e.g., the top surface) of the insulation structure 18. An interconnection layer 201 may be formed or disposed on a sidewall and a bottom wall of the through hole 183. The interconnection layer 201 may contact the exposed portion of the second conductive layer 14. The first conductive layer 19 may physically connect and electrically connect the interconnection layer 201. Thus, the first conductive layer 19 may be electrically connected to the circuit structure 12 through the interconnection layer 201.

Meanwhile, the interconnection layer 201 may form a via structure 20 in the through hole 183. The via structure 20 may extend through the insulation structure 18 (including the first insulation layer 15, the second insulation layer 16 and the third insulation layer 17). The via structure 20 may include the interconnection layer 201 formed or disposed on the sidewall and the bottom wall of the through hole 183. The via structure 20 may contact the second conductive layer 14, and may electrically connect the first conductive layer 19 and the circuit structure 12.

In some embodiments, the first conductive layer 19 may include a metal layer such as an aluminum (Al) layer or a copper (Cu) layer. The material of the first conductive layer 19 may be the same as or different from the material of the second conductive layer 14. In some embodiments, the interconnection layer 201 may include a metal layer such as an aluminum (Al) layer or a copper (Cu) layer. The material of the interconnection layer 201 may be the same as or different from the material of the first conductive layer 19.

The interconnection layer 201 and the first conductive layer 19 may be formed concurrently and integrally. The interconnection layer 201 may be also referred to as an extending of the first conductive layer 19. In addition, the first conductive layer 19 may include a main portion 190 disposed on the first surface 181 (e.g., the top surface) of the insulation structure 18. The main portion 190 may include a first segment 193 and a second segment 194, and may define a gap 195 between the first segment 193 and the second segment 194. Thus, the main portion 190 may be patterned. The first segment 193 may be separated from the second segment 194 through the gap 195. A portion of the third insulation layer 17 of the insulation structure 18 may be exposed in the gap 195.

The main portion 190 of the first conductive layer 19 may have a thickness T7. The interconnection layer 201 may have a thickness T4. The thickness T7 of the main portion 190 of the first conductive layer 19 may be greater than the thickness T4 of the interconnection layer 201. The thickness T7 of the main portion 190 of the first conductive layer 19 may be 2.6 μm to 3.0 μm. For example, the thickness T7 may be about 2.8 μm. The thickness T4 of the interconnection layer 201 may be 0.4 μm to 1.5 μm. For example, the thickness T4 may be about 0.5 or about 1.0 μm.

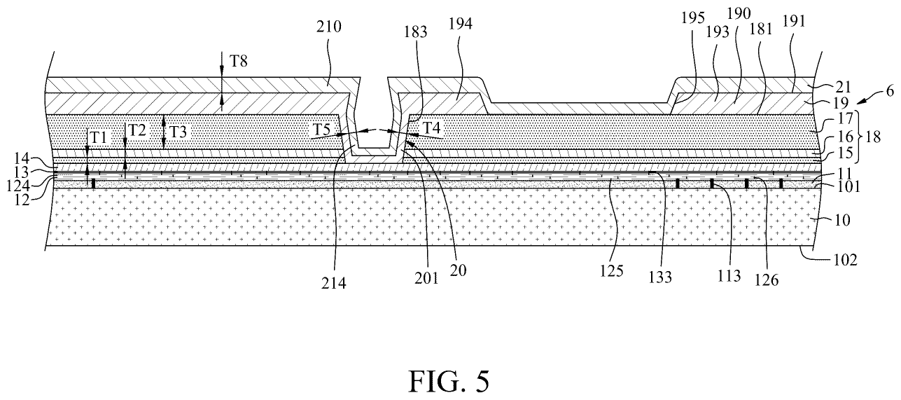

With reference to FIG. 5, at step S904, a first outer layer 21 may be formed or disposed on the first conductive layer 19 by, for example, deposition. The first outer layer 21 may be a passivation layer or an electrical insulation layer, and may include an oxide material or a nitride material, such as SiO₂, SiN, Si₃N₄ and/or SiCN. In some embodiments, the first outer layer 21 may include an oxide material such as tetraethoxysilane (Si(OC2H5)₄, TEOS). The first outer layer 21 may include a main portion 210 and a first extending portion 214 extending from the main portion 210. The main portion 210 of the first outer layer 21 may be disposed on the main portion 190 of the first conductive layer 19. A portion of the first outer layer 21 may be disposed in the gap 195 of the first conductive layer 19 to contact the exposed portion of the third insulation layer 17 of the insulation structure 18. The first extending portion 214 of the first outer layer 21 may be disposed on the interconnection layer 201 and may extend into the through hole 183.

The main portion 210 of the first outer layer 21 may have a thickness T8. The first extending portion 214 of the first outer layer 21 may have a thickness T5. The thickness T8 of the main portion 210 of the first outer layer 21 may be greater than the thickness T5 of the first extending portion 214 of the first outer layer 21. The thickness T8 of the main portion 210 of the first outer layer 21 may be 1.5 μm to 3.0 μm. For example, the thickness T8 may be about 2.0 μm. The thickness T5 of the first extending portion 214 of the first outer layer 21 may be 0.5 μm to 1.5 μm. For example, the thickness T5 may be about 1.0 μm. The first extending portion 214 of the first outer layer 21 may not fill the through hole 183.

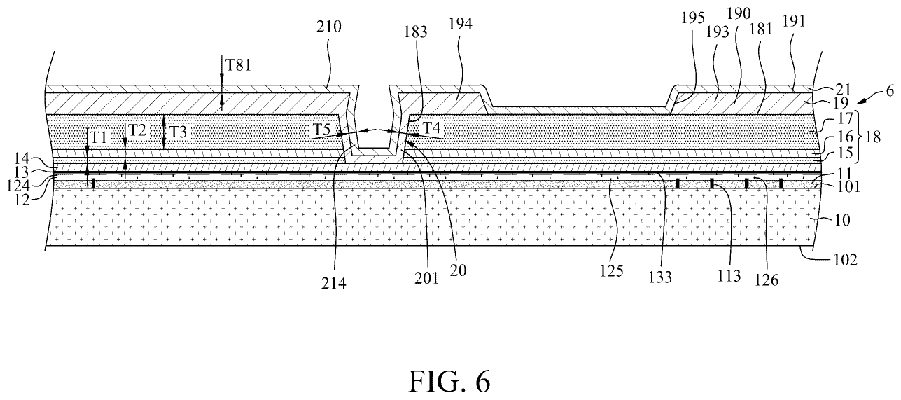

With reference to FIG. 6, the main portion 210 of the first outer layer 21 may be thinned by, for example, etching. The thickness T8 of the main portion 210 of the first outer layer 21 of FIG. 5 may be reduced to the thickness T81. The thickness T81 of the main portion 210 of the first outer layer 21 may be 0.5 μm to 1.5 μm. For example, the thickness T81 may be about 1.0 μm.

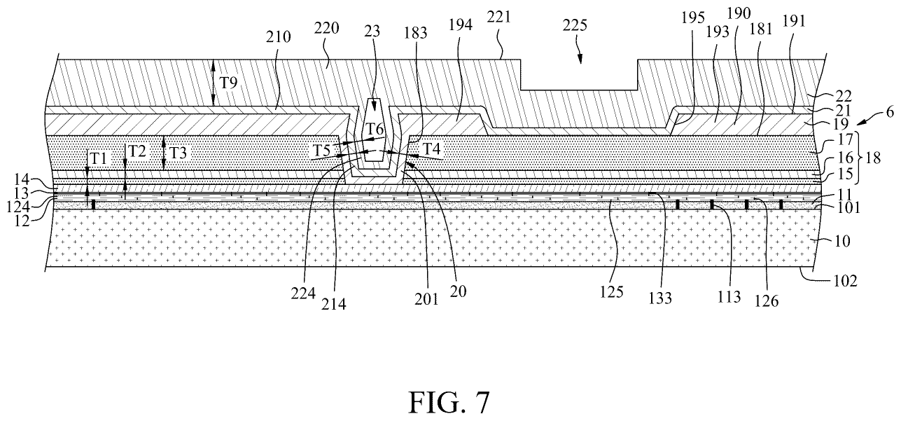

With reference to FIG. 7, at step S905, a second outer layer 22 may be formed or disposed on the first outer layer 21 by, for example, deposition. The second outer layer 22 may be also referred to as “an outermost layer”. The second outer layer 22 may be a passivation layer or an electrical insulation layer, and may include an oxide material or a nitride material, such as SiO₂, SiN, Si₃N₄ and/or SiCN. In some embodiments, the second outer layer 22 may include an oxide material such as tetraethoxysilane (Si(OC2H5)₄, TEOS). The material of the second outer layer 22 may be same as or different form the material of the first outer layer 21.

The second outer layer 22 may include a main portion 220 and a second extending portion 224 extending from the main portion 220. The main portion 220 of the second outer layer 22 may be disposed on the main portion 210 of the first outer layer 21. A portion of the second outer layer 22 may be disposed in the gap 195 of the first conductive layer 19 so as to define a recess portion 225 recessed from a first surface 221 (e.g., a top surface) of the main portion 220 of the second outer layer 22. The first surface 221 (e.g., a top surface) of the main portion 220 of the second outer layer 22 may face away from the first outer layer 21, and may be also referred to as “an outermost surface 221” of the second outer layer 22. The second extending portion 224 of the second outer layer 22 may be disposed on the first extending portion 214 of the first outer layer 21, and may extend into the through hole 183.

The main portion 220 of the second outer layer 22 may have a thickness T9. The second extending portion 224 of the second outer layer 22 may have a thickness T6. The thickness T9 of the main portion 220 of the second outer layer 22 may be greater than the thickness T6 of the second extending portion 224 of the second outer layer 22. The thickness T9 of the main portion 220 of the second outer layer 22 may be 5.0 μm to 7.0 μm. For example, the thickness T9 may be about 6.0 μm. The thickness T6 of the second extending portion 224 of the second outer layer 22 may be 0.5 μm to 1.5 μm or 0.9 μm to 1.1 μm. For example, the thickness T6 may be about 1.0 μm.

The second extending portion 224 of the second outer layer 22 may not fill the through hole 183. The main portion 220 of the second outer layer 22 and the second extending portion 224 of the second outer layer 22 may collectively define an enclosed void 23. Thus, the second outer layer 22 may define the enclosed void 23. The enclosed void 23 is an enclosed space filled with air. The enclosed void 23 may horizontally overlap the first outer layer 21. The enclosed void 23 may horizontally overlap the first conductive layer 19. The enclosed void 23 may horizontally overlap the insulation structure 18. The enclosed void 23 may horizontally overlap the via structure 20. A top portion of the enclosed void 23 may extend beyond a top surface of the first outer layer 21.

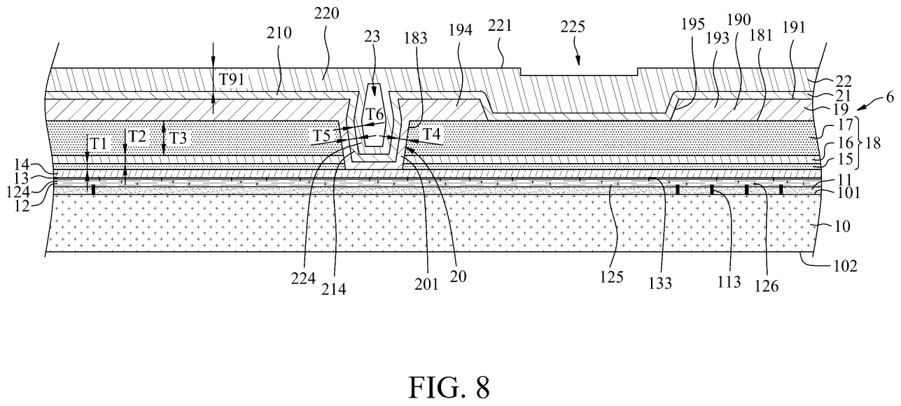

With reference to FIG. 8, the main portion 220 of the second outer layer 22 may be thinned by, for example, performing a chemical-mechanical polishing (CMP) process to the first surface 221 (i.e., the outermost surface) of the main portion 220 of the second outer layer 22. Thus, the first surface 221 (i.e., the outermost surface) of the main portion 220 of the second outer layer 22 may be planarized. The thickness T9 of the main portion 220 of the second outer layer 22 of FIG. 7 may be reduced to the thickness T91. The thickness T91 of the main portion 220 of the second outer layer 22 may be 2.0 μm to 4.0 μm. For example, the thickness T91 may be 3.0 μm. In addition, the depth of the recess portion 225 may be reduced.

In the present disclosure, the second outer layer 22 may include an oxide material such as tetraethoxysilane (Si(OC2H5)₄, TEOS) so as to improve the coplanarity and flatness of the first surface 221 (i.e., the outermost surface) of the main portion 220 of the second outer layer 22 after the thinning and planarization process. For example, the first surface 221 (i.e., the outermost surface) of the main portion 220 of the second outer layer 22 may have a better coplanarity and flatness as compared with when the second outer layer 22 includes a cured photoresist material (e.g., polyimide).

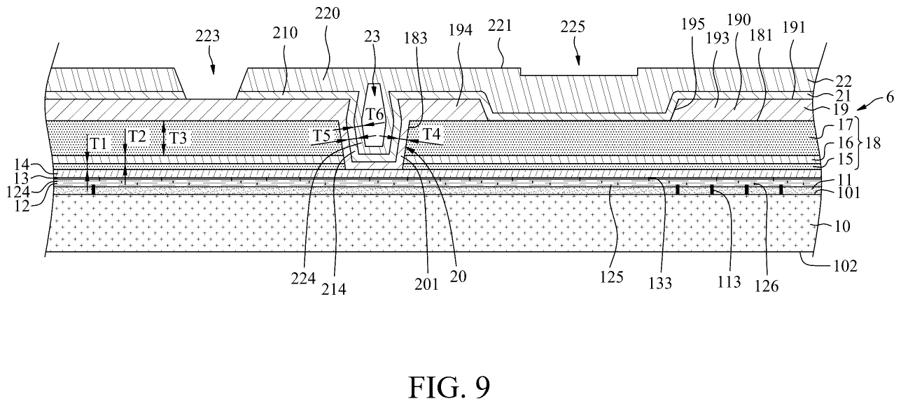

With reference to FIG. 9, at least one opening 223 may be formed to extend through the second outer layer 22 and the first outer layer 21 to expose a portion of the first conductive layer 19. Thus, the second outer layer 22 and the first outer layer 21 may collectively define the opening 223.

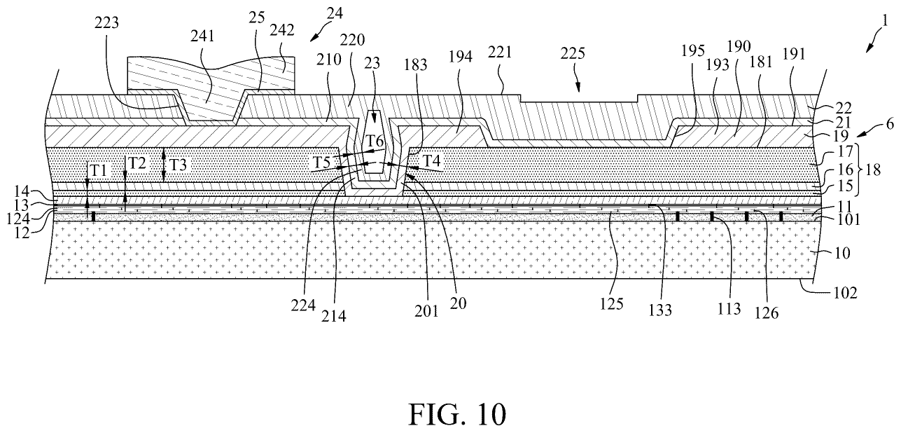

With reference to FIG. 10, at step S906, at least one bump 24 may be formed or disposed in the opening 223. The bump 24 may be formed or disposed on the second outer layer 22, and may electrically connect the first conductive layer 19. In some embodiments, the bump 24 may include a main portion 241 and an extending portion 242. The main portion 241 may be disposed in the opening 223, may extend through the first outer layer 21 and the second outer layer 22, and may contact the first conductive layer 19. The extending portion 242 may be disposed on the first surface 221 (i.e., the outermost surface) of the main portion 220 of the second outer layer 22. Thus, the bump 24 may extend through the outermost layer 22, and may extend beyond the first surface 221 (i.e., the outermost surface) of the main portion 220 of the second outer layer 22.

In some embodiments, a seed layer 25 may be under the bump 24. Thus, the seed layer 25 may be disposed between the bump 24 and the second outer layer 22. Alternatively, the seed layer 25 may be a portion of the bump 24.

In the present disclosure, the first surface 221 (i.e., the outermost surface) of the main portion 220 of the second outer layer 22 may have a good coplanarity and flatness. That is, the first surface 221 (i.e., the outermost surface) of the main portion 220 of the second outer layer 22 may not have an irregular morphology (e.g., a wave-like profile). The first surface 221 (i.e., the outermost surface) of the main portion 220 of the second outer layer 22 may be a flat surface rather than a wavy surface. Therefore, a plurality of bumps 24 may have a uniform shape, and the bumps 24 will not tilt. The bumps 24 may be disposed at a same elevation.

Meanwhile, an electronic device 1 may be formed or obtained. In some embodiments, a singulation process may be conducted so as to form a plurality of electronic devices 1. The electronic device 1 may be also referred to as “a first electronic device”, “a top electronic device”, “a first semiconductor die”, “a top semiconductor die”, “a first semiconductor chip” or “a top semiconductor chip”. The electronic device 1 may be a logic die such as an application processor (AP) die or an application specific integrated circuit (ASIC) die. Alternatively, the electronic device 1 may be a memory die or a memory chip.

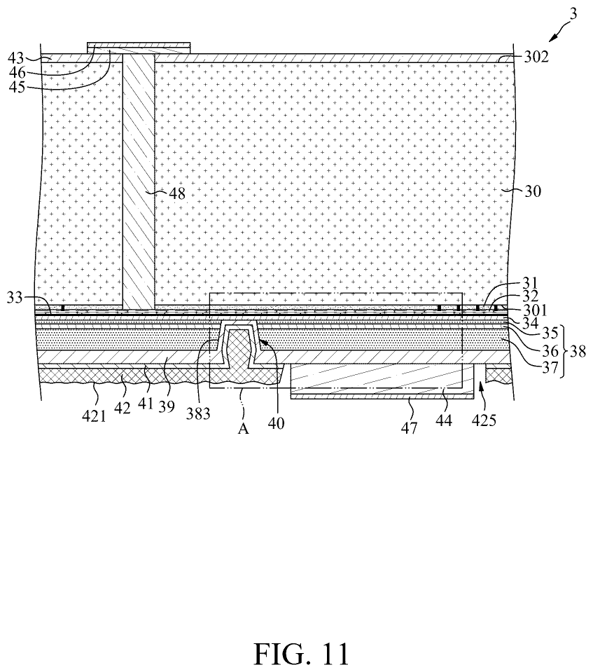

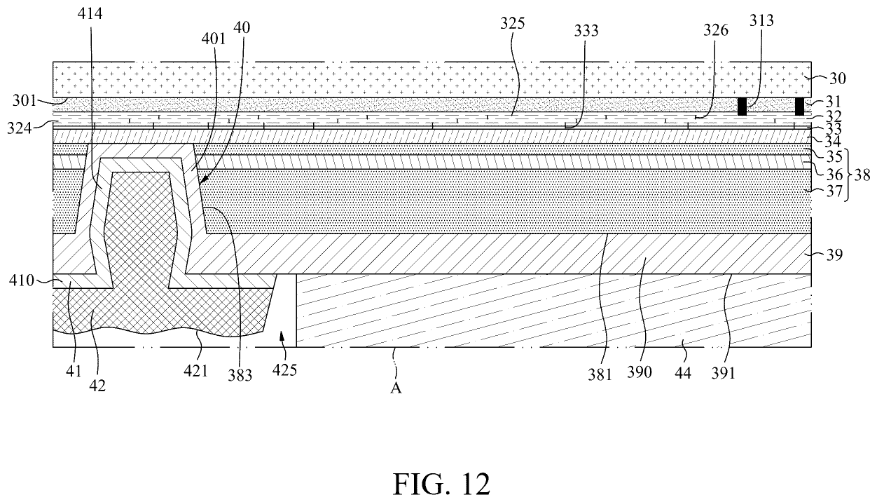

With reference to FIG. 11 and FIG. 12, wherein FIG. 12 illustrates an enlarged view of an area “A” of FIG. 11, a second electronic device 3 may be provided. The second electronic device 3 may be also referred to as “a bottom electronic device”, “a second semiconductor die”, “a bottom semiconductor die”, “a second semiconductor chip” or “a bottom semiconductor chip”. The second electronic device 3 may be a logic die such as an application processor (AP) die or an application specific integrated circuit (ASIC) die. Alternatively, the second electronic device 3 may be a memory die or a memory chip.

The second electronic device 3 may include a base portion 30 (e.g., a second base portion), a first intermediate layer 31, a plurality of first interconnection vias 313, a circuit structure 32 (e.g., a second circuit structure), a second intermediate layer 33, a plurality of second interconnection vias 333, a second conductive layer 34, an insulation structure 38 (e.g., a second insulation structure), a first conductive layer 39, a first outer layer 41, a second outer layer 42, a through via 48, a third outer layer 43, a pad 45 and a connecting element 44.

The base portion 30 may have a first surface 301 and a second surface 302 opposite to the first surface 301. The first surface 301 may be an active surface. The second surface 302 may be a back side surface.

In some embodiments, the base portion 30 may be a substrate, and may include a dielectric material, such as an oxide material or a nitride material. Alternatively, the base portion 30 may be a substrate, and may include, for example, silicon (Si), germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

In some embodiments, the base portion 30 may be a semiconductor device that includes a circuit, such as a memory cell. In some embodiments, the memory cell may include a dynamic random access memory cell (DRAM cell).

In addition, the base portion 30 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof.

The first intermediate layer 31 may be disposed between the first surface 301 of the base portion 30 and the circuit structure 32. The first intermediate layer 31 may be also referred to as “a lower intermediate layer” or “an upper intermediate layer”. The first intermediate layer 31 may be configured to electrically insulate the circuit structure 32 form the first surface 301 of the base portion 30. Thus, the circuit structure 32 is electrically insulated form the first surface 301 of the base portion 30 through the first intermediate layer 31. In some embodiments, the first intermediate layer 31 may include a dielectric material or an electrical insulation material, such as an oxide material or a nitride material.

The first interconnection vias 313 may be disposed in the first intermediate layer 31. The first interconnection vias 313 may extend through the first intermediate layer 31, and may be configured to electrically connect the circuit structure 32 and the first surface 301 of the base portion 30. Thus, the circuit structure 32 is electrically connected to the first surface 301 of the base portion 30 through the first interconnection vias 313. In some embodiments, the first interconnection vias 313 may include an electrically conductive material, such as a metal material. For example, the first interconnection vias 313 may include copper (Cu).

The circuit structure 32 may be disposed on the first intermediate layer 31 and the first surface 301 of the base portion 30. In some embodiments, the first intermediate layer 31 may be disposed on and may contact the first surface 301 of the base portion 30. The circuit structure 32 may be disposed on and may contact the first intermediate layer 31. Alternatively, there may be at least one layer (e.g., insulation layer or conductive layer) between the circuit structure 32 and the first surface 301 of the base portion 30.

The circuit structure 32 may be a redistribution layer (RDL) structure, and may include a plurality of dielectric layers 324, a plurality of redistribution layers (RDLs) 325 and a plurality of inner vias 326. The dielectric layers 324 may be interlayer dielectric (ILD) layers, and may include SiO₂, SiN, and/or SiCN. The redistribution layers (RDLs) 325 and the inner vias 326 are embedded in the dielectric layers 324. The redistribution layers (RDLs) 325 may include a plurality of traces and a plurality of pads. The redistribution layers (RDLs) 325 are electrically connected to one another through the inner vias 326. The circuit structure 32 may be also referred to as “a conductive structure”. In some embodiments, the redistribution layers (RDLs) 325 may be electrically connected to the first interconnection vias 313.

The second intermediate layer 33 may be disposed between the second conductive layer 34 and the circuit structure 32. The second intermediate layer 33 may be also referred to as “a lower intermediate layer” or “an upper intermediate layer”. The second intermediate layer 33 may be configured to electrically insulate the circuit structure 32 form the second conductive layer 34. Thus, the circuit structure 32 is electrically insulated form the second conductive layer 34 through the second intermediate layer 33. In some embodiments, the second intermediate layer 33 may include a dielectric material or an electrical insulation material, such as an oxide material or a nitride material.

The second interconnection vias 333 may be disposed in the second intermediate layer 33. The second interconnection vias 333 may extend through the second intermediate layer 33, and may be configured to electrically connect the circuit structure 32 and the second conductive layer 34. Thus, the circuit structure 32 is electrically connected to the second conductive layer 34 through the second interconnection vias 333. In some embodiments, the second interconnection vias 333 may include an electrically conductive material, such as a metal material. For example, the second interconnection vias 333 may include copper (Cu).

The second conductive layer 34 may be disposed between the circuit structure 32 and the insulation structure 38. In some embodiments, the second intermediate layer 33 may cover and contact the circuit structure 32. The second conductive layer 34 may be interposed between the second intermediate layer 33 and the insulation structure 38. In some embodiments, the second conductive layer 34 may include a metal layer such as an aluminum (Al) layer or a copper (Cu) layer, and may cover and contact the second intermediate layer 33. The second conductive layer 34 may be electrically connected to the circuit structure 32 through the second interconnection vias 333.

The insulation structure 38 may be disposed on the circuit structure 32. In some embodiments, the insulation structure 38 may cover and contact the second conductive layer 34. The insulation structure 38 may include a first insulation layer 35, a second insulation layer 36 and a third insulation layer 37. Thus, the first insulation layer 35, the second insulation layer 36 and the third insulation layer 37 may collectively define the insulation structure 38. The insulation structure 38 may have a first surface 381 (e.g., a top surface) facing away from the circuit structure 32 and the base portion 30.

The first insulation layer 35 may be disposed on the circuit structure 12. The first insulation layer 35 may cover and contact the second conductive layer 34. The first insulation layer 35 may be a passivation layer or an electrical insulation layer, and may include an oxide material or a nitride material, such as SiO₂, SiN, Si₃N₄ and/or SiCN. The first insulation layer 35 may be a buffer layer. The first insulation layer 35 may have a first thickness.

The second insulation layer 36 may be disposed on or disposed over the first insulation layer 35. The second insulation layer 36 may be interposed between the first insulation layer 35 and the third insulation layer 37. The second insulation layer 36 may cover and contact the first insulation layer 35. The second insulation layer 36 may be a passivation layer or an electrical insulation layer, and may include an oxide material or a nitride material, such as SiO₂, SiN, Si₃N₄ and/or SiCN. The second insulation layer 36 may be a protection layer and may prevent the external moisture from entering the circuit structure 32 and the first surface 301 of the base portion 30. A material of the second insulation layer 36 may be different from a material of the first insulation layer 35. The second insulation layer 36 may have a second thickness.

The third insulation layer 37 may be disposed on the second insulation layer 36. The third insulation layer 37 may cover and contact the second insulation layer 36. A first surface (e.g., a top surface) of the third insulation layer 37 may be the first surface 381 (e.g., the top surface) of the insulation structure 38. The third insulation layer 37 may be a passivation layer or an electrical insulation layer, and may include an oxide material or a nitride material, such as SiO₂, SiN, Si₃N₄ and/or SiCN. The third insulation layer 37 may have a third thickness. A material of the third insulation layer 37 may be the same as the material of the first insulation layer 35. The material of the third insulation layer 37 may be different from the material of the second insulation layer 36. For example, the third insulation layer 37 may include oxide material, the first insulation layer 35 may include oxide material, and the second insulation layer 36 may include nitride material.

The third thickness of the third insulation layer 37 may be greater than the second thickness of the second insulation layer 36 and the first thickness of the first insulation layer 35. The second thickness of the second insulation layer 36 may be greater than the first thickness of the first insulation layer 35.

The insulation structure 38 may define a through hole 383 extending through the insulation structure 38 and exposing a portion of the second conductive layer 34. The first conductive layer 39 may be formed or disposed on the first surface 381 of the insulation structure 38. The first conductive layer 39 may have a first surface 391 facing away from the first surface 381 of the insulation structure 38. An interconnection layer 401 may be formed or disposed on a sidewall and a bottom wall of the through hole 383. The interconnection layer 401 may contact the exposed portion of the second conductive layer 34. The first conductive layer 39 may physically connect and electrically connect the interconnection layer 401. Thus, the first conductive layer 39 may be electrically connected to the circuit structure 32 through the interconnection layer 401.

Meanwhile, the interconnection layer 401 may form a via structure 40 in the through hole 383. The via structure 40 may extend through the insulation structure 38 (including the first insulation layer 35, the second insulation layer 36 and the third insulation layer 37). The via structure 40 may include the interconnection layer 401 formed or disposed on the sidewall and the bottom wall of the through hole 383. The via structure 40 may contact the second conductive layer 34, and may electrically connect the first conductive layer 39 and the circuit structure 32.

In some embodiments, the first conductive layer 39 may include a metal layer such as an aluminum (Al) layer or a copper (Cu) layer. The material of the first conductive layer 39 may be the same as or different from the material of the second conductive layer 34. In some embodiments, the interconnection layer 401 may include a metal layer such as an aluminum (Al) layer or a copper (Cu) layer. The material of the interconnection layer 401 may be the same as or different from the material of the first conductive layer 39.

The interconnection layer 401 and the first conductive layer 39 may be formed concurrently and integrally. The interconnection layer 401 may be also referred to as an extending of the first conductive layer 39. In addition, the first conductive layer 39 may include a main portion 390 disposed on the first surface 381 of the insulation structure 38. The main portion 390 of the first conductive layer 39 may have a thickness. The interconnection layer 401 may have a thickness. The thickness of the main portion 390 of the first conductive layer 39 may be greater than the thickness of the interconnection layer 401.

The first outer layer 41 may be formed or disposed on the first conductive layer 39. The first outer layer 41 may include a metal layer such as copper (Cu) layer. The first outer layer 41 may include a main portion 410 and a first extending portion 414 extending from the main portion 410. The main portion 410 of the first outer layer 41 may be disposed on the main portion 390 of the first conductive layer 39. The first extending portion 414 of the first outer layer 41 may be disposed on the interconnection layer 401 and may extend into the through hole 383.

The main portion 410 of the first outer layer 41 may have a thickness. The first extending portion 414 of the first outer layer 41 may have a thickness. The thickness of the main portion 410 of the first outer layer 41 may be substantially equal to the thickness of the first extending portion 414 of the first outer layer 41.

The second outer layer 42 may be formed or disposed on the first outer layer 41 or on the first conductive layer 39 by, for example, deposition. The second outer layer 42 may be also referred to as “an outer layer” or “an outermost layer”. The second outer layer 42 may include a cured photoresist material (e.g., polyimide). The material of the second outer layer 42 of the second electronic device 3 is different from the material of the second outer layer 22 (e.g., the outermost layer) of the electronic device 1.

The second outer layer 42 may have a first surface 421 facing away from the first outer layer 41, and may be also referred to as “an outermost surface 421” of the second outer layer 42. The first surface 421 (e.g., the outermost surface 421) of the second outer layer 42 may be a wavy surface. A portion of the second outer layer 42 may be disposed on the first extending portion 414 of the first outer layer 41, and may fill the through hole 383.

The second outer layer 42 and the first outer layer 41 may collectively define an opening 425 to expose a portion of the first surface 391 of the first conductive layer 39. The connecting element 44 may be disposed adjacent to the first surface 301 of the base portion 30 of the second electronic device 3. The connecting element 44 (e.g., a pillar, a bump or a pad) may be formed or disposed on the exposed portion of the first surface 391 of the first conductive layer 39 the opening 425. The opening 425 of the second outer layer 42 may be configured for accommodating the connecting element 44.

The connecting element 44 may include a metal material such as copper (Cu) or aluminum (Al). The connecting element 44 may contact and electrically connect the first conductive layer 39. In some embodiments, a metal layer 47 may be disposed on the connecting element 44. The metal layer 47 may be a barrier layer such as nickel (Ni) layer, palladium (Pd) layer and/or gold (Au) layer.

The third outer layer 43 may be disposed or formed on the second surface 302 of the base portion 30. The third outer layer 43 may be a passivation layer or an electrical insulation layer, and may include an oxide material or a nitride material, such as SiO₂, SiN, Si₃N₄ and/or SiCN.

The through via 48 may be disposed in the base portion 30. The through via 48 may include a metal material such as copper (Cu). The through via 48 may extend through the third outer layer 43, the base portion 30 and the first intermediate layer 31. A bottom end of the through via 48 may contact the circuit structure 32. A top end of the through via 48 may be exposed by the third outer layer 43.

The pad 45 may be disposed adjacent to the second surface 302 of the base portion 30 of the second electronic device 3. The pad 45 may be formed or disposed on the outer layer 43, and may cover and contact the top end of the through via 48. The pad 45 may electrically connect the through via 48. Thus, the connecting element 44 may be electrically connected to the pad 45 through the through via 48. A material of the pad 45 may include copper (Cu), aluminum (Al) or tin (Sn). In some embodiments, a metal layer 46 may be disposed on the pad 45. The metal layer 46 may be a barrier layer such as nickel (Ni) layer, palladium (Pd) layer, copper (Cu) layer and/or gold (Au) layer.

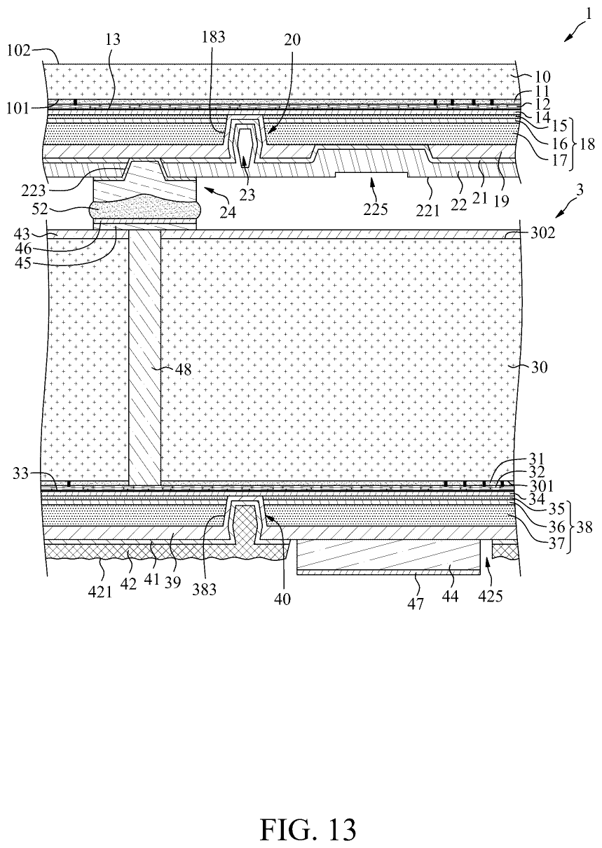

With reference to FIG. 13, the electronic device 1 (e.g., the first electronic device 1) may be bonded to and electrically connected to the second electronic device 3. For example, the pad 45 of the second electronic device 3 may be electrically connected to the bump 24 of the first electronic device 1 through a first solder material 52. The first solder material 52 may include a reflowable material such as AgSn.

In the present disclosure, the first surface 221 (i.e., the outermost surface) of the main portion 220 of the second outer layer 22 may have a good coplanarity and flatness. Thus, the bumps 24 will not tilt on the first surface 221 (i.e., the outermost surface) of the main portion 220 of the second outer layer 22. Therefore, the joint or bonding formed by the bumps 24 of the first electronic device 1 and the pads 45 of the second electronic device 3 may be secured. The yield rate may be improved.

In some embodiments, if the electronic device 1 (e.g., the first electronic device 1) in FIG. 13 is a singulated device, then, a singulation process may be conducted to the second electronic device 3. If the electronic device 1 (e.g., the first electronic device 1) in FIG. 13 has not been singulated, then, a singulation process may be conducted to the electronic device 1 (e.g., the first electronic device 1) and the second electronic device 3 concurrently. Thus, the electronic device 1 (e.g., the first electronic device 1) and the second electronic device 3 may be singulated concurrently.

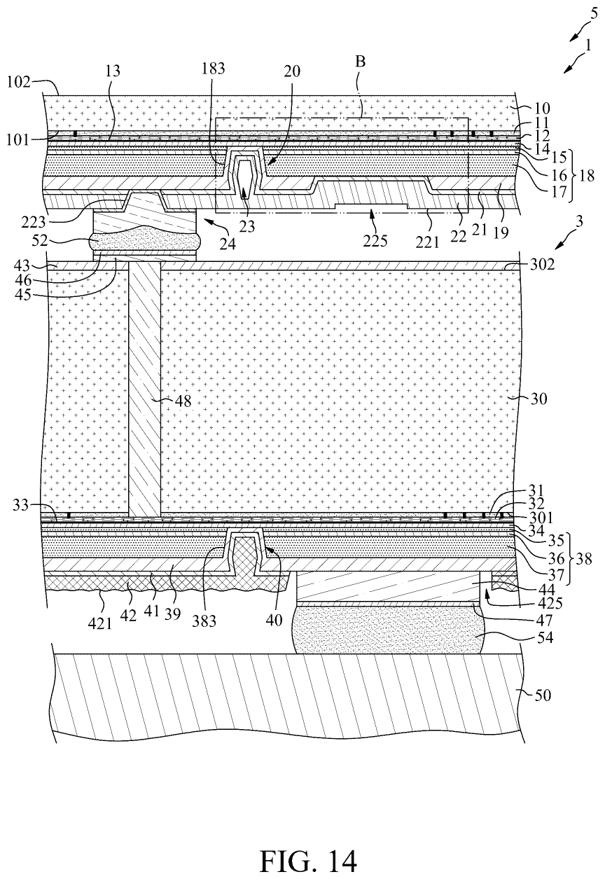

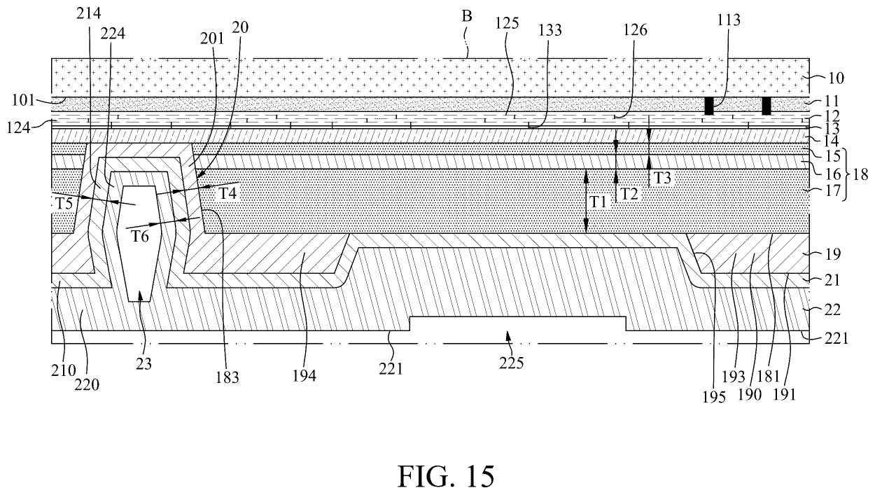

With reference to FIG. 14 and FIG. 15, wherein FIG. 15 illustrates an enlarged view of an area “B” of FIG. 14, the second electronic device 3 may be bonded to and electrically connected to a substrate 50 as so to form or obtain an assembly structure 5. For example, the substrate 50 may be electrically connected the connecting element 44 of the second electronic device 3 through a second solder material 54. The second solder material 54 may include a reflowable material such as AgSn. The substrate 50 may include a printed circuit board (PCB), a core substrate or a coreless substrate.

One aspect of the present disclosure provides an electronic device. The electronic device includes a base portion, a circuit structure, an insulation structure, a first conductive layer, a via structure, a first outer layer and a second outer layer. The base portion has a first surface. The circuit structure is disposed on the first surface of the base portion. The insulation structure is disposed on the circuit structure. The first conductive layer is disposed on the insulation structure. The via structure extends through the insulation structure, and electrically connects the first conductive layer and the circuit structure. The first outer layer is disposed on the first conductive layer. The second outer layer is disposed on the first outer layer. The second outer layer includes an oxide material so as to improve a coplanarity of an outermost surface of the second outer layer.

Another aspect of the present disclosure provides an assembly structure. The assembly structure includes a first electronic device, a second electronic device and a substrate. The first electronic device includes a base portion, an outermost layer and a bump. The base portion has a first surface. The outermost layer is disposed adjacent to the first surface of the base portion. The outermost layer includes an oxide material so as to improve a coplanarity of an outermost surface of the outermost layer. The bump extends through the outermost layer and extends beyond the outermost surface of the outermost layer. The second electronic device includes a base portion, a through via, a pad and a connecting element. The base portion has a first surface and a second surface opposite to the first surface. The through via extends through the base portion. The pad is disposed adjacent to the second surface of the base portion of the second electronic device, and electrically connects the through via and the bump of the first electronic device. The connecting element is disposed adjacent to the first surface of the base portion of the second electronic device, and is electrically connected to the pad through the through via. The substrate is electrically connected to the connecting element.

Another aspect of the present disclosure provides a method of manufacturing an electronic device. The method includes: providing a main body including a base portion having a first surface, a circuit structure disposed on the first surface of the base portion, and an insulation structure disposed on the circuit structure; forming a through hole extending through the insulation structure; forming a first conductive layer on the insulation structure and forming an interconnection layer on a sidewall of the through hole, wherein the first conductive layer connects the interconnection layer, wherein the first conductive layer is electrically connected to the circuit structure through the interconnection layer; forming a first outer layer on the first conductive layer; and forming a second outer layer on the first outer layer, wherein the second outer layer includes an oxide material.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An assembly structure, comprising:
a first electronic device, comprising:
a base portion having a first surface;
an outermost layer disposed adjacent to the first surface of the base portion, wherein the outermost layer includes an oxide material so as to improve a coplanarity of an outermost surface of the outermost layer; and
a bump extending through the outermost layer and extending beyond the outermost surface of the outermost layer;
a second electronic device, comprising:
a base portion having a first surface and a second surface opposite to the first surface;
a through via extending through the base portion;
a pad disposed adjacent to the second surface of the base portion of the second electronic device, and electrically connecting the through via and the bump of the first electronic device; and
a connecting element disposed adjacent to the first surface of the base portion of the second electronic device, and electrically connected to the pad through the through via; and
a substrate electrically connected to the connecting element.

2. The assembly structure of claim 1, wherein the outermost layer includes tetraethoxysilane (TEOS) oxide material.

3. The assembly structure of claim 1, wherein the base portion of the first electronic device includes silicon (Si), and the base portion of the second electronic device includes silicon (Si).

4. The assembly structure of claim 1, wherein the first surface of the base portion of the first electronic device is an active surface, and the first surface of the base portion of the second electronic device is an active surface.

5. The assembly structure of claim 1, wherein the first electronic device further includes:
a circuit structure disposed on the first surface of the base portion;
an insulation structure disposed on the circuit structure;
a first conductive layer disposed on the insulation structure;
a via structure extending through the insulation structure, and electrically connecting the first conductive layer and the circuit structure; and
a first outer layer disposed on the first conductive layer, wherein the outermost layer is disposed on the first outer layer.

6. The assembly structure of claim 5, wherein the insulation structure comprises:
a first insulation layer disposed on the circuit structure;
a second insulation layer disposed on the first insulation layer; and
a third insulation layer disposed on the second insulation layer, wherein the via structure extends through the first insulation layer, the second insulation layer and the third insulation layer.

7. The assembly structure of claim 6, wherein the third insulation layer includes oxide material, the first insulation layer includes oxide material, and the second insulation layer include nitride material.

8. The assembly structure of claim 1, wherein the outermost layer of the first electronic device defines an enclosed void.

9. The assembly structure of claim 1, wherein the pad of the second electronic device is electrically connected to the bump of the first electronic device through a first solder material.

10. The assembly structure of claim 1, wherein the substrate is electrically connected the connecting element of the second electronic device through a second solder material.

11. The assembly structure of claim 1, wherein the second electronic device further includes:
a circuit structure disposed on the first surface of the base portion;
an insulation structure disposed on the circuit structure;
a first conductive layer disposed on the insulation structure;
a via structure extending through the insulation structure, and electrically connecting the first conductive layer and the circuit structure; and
an outer layer disposed on the first conductive layer.

12. The assembly structure of claim 11, wherein the outer layer defines an opening for accommodating the connecting element, and the connecting element contacts the first conductive layer.

13. The assembly structure of claim 11, wherein a material of the outer layer of the second electronic device is different from a material of the outermost layer of the first electronic device.

14. The assembly structure of claim 11, wherein the insulation structure comprises:
a first insulation layer disposed on the circuit structure;
a second insulation layer disposed on the first insulation layer; and
a third insulation layer disposed on the second insulation layer, wherein the via structure extends through the first insulation layer, the second insulation layer and the third insulation layer.

15. A method of manufacturing an electronic device, comprising:
providing a main body including a base portion having a first surface, a circuit structure disposed on the first surface of the base portion, and an insulation structure disposed on the circuit structure;
forming a through hole extending through the insulation structure;
forming a first conductive layer on the insulation structure and forming an interconnection layer on a sidewall of the through hole, wherein the first conductive layer connects the interconnection layer, wherein the first conductive layer is electrically connected to the circuit structure through the interconnection layer;
forming a first outer layer on the first conductive layer; and
forming a second outer layer on the first outer layer, wherein the second outer layer includes an oxide material.

16. The method of claim 15, wherein the interconnection layer and the first conductive layer are formed concurrently and integrally.

17. The method of claim 15, wherein before forming the second outer layer, the method further comprises:
thinning the first outer layer.

18. The method of claim 15, further comprising:
planarizing an outermost surface of the second outer layer.

19. The method of claim 18, wherein the step of planarizing the outermost surface of the second outer layer includes:
performing a chemical-mechanical polishing (CMP) process to the outermost surface of the second outer layer.
